(19) United States
(12) Patent Application Publication
(10) Pub. No.: US 2018/0151684 A1
(43) Pub. Date: May 31, 2018

(54) METHOD TO FORM OHMIC CONTACTS TO SEMICONDUCTORS USING QUANTIZED METALS

(71) Applicant: Intel Corporation, Santa Clara, CA (US)

(72) Inventors: Benjamin CHU-KUNG, Portland, OR (US); Van H. LE, Portland, OR (US); Rafael RIOS, Austin, TX (US); Gilbert DEWEY, Hillsboro, OR (US); Scott B. CLENDENNING, Portland, OR (US); Jack T. KAVALIEROS, Portland, OR (US)

(21) Appl. No.: 15/576,253

(22) PCT Filed: Jun. 27, 2015
(86) PCT No.: PCT/US2015/038191

§ 371 Date: Nov. 21, 2017

(51) Int. Cl. H01L 29/45; H01L 21/768; H01L 21/285; H01L 29/417; H01L 29/66; H01L 29/78

(52) U.S. Cl. CPC H01L 29/45; H01L 21/76802; H01L 21/28568; H01L 29/0847; H01L 29/66568; H01L 21/76883; H01L 29/78; H01L 29/41783

(57) ABSTRACT

An apparatus including an integrated circuit device including at least one low density of state metal/semiconductor material interface, wherein the at least one low density of state metal is quantized. An apparatus including an integrated circuit device including at least one interface of a low density of state metal and a semiconductor material, wherein a contact area of the metal at the interface is graded. A method including confining a contact area of a semiconductor material; and forming a metal contact in the contact area.

### BACKGROUND

### Field

Integrated circuit devices.

### Description of Related Art

Integrated circuit devices often employ metal to semiconductor contacts. One example is a contact to a junction region (source or drain region) of a transistor device.

While metal is deposited onto a semiconductor material, the dangling bonds at the semiconductor surface makes it such that the Fermi level of the metal and semiconductor material do not match. The result is a pinning of the Fermi level in a semiconductor to a particular level (a level in a bandgap) which creates a barrier for carriers to travel through. As metal to semiconductor contact areas and integrated circuit devices gets smaller, the resistance associated with such contact area gets larger (contact resistance is proportional into the inverse of the contact area). Thus, the contact resistance becomes a larger percentage of the overall parasitics of a device. Solutions to address contact resistance include creating a less reactive contact and lowering a bandgap interfacial contact or the use of a lower bandgap interfacial contact layer.

### BRIEF DESCRIPTION OF THE DRAWINGS

FIG. 1 shows the embodiment of a cross-sectional side view of a transistor device having metal contacts to junction regions of the device.

FIG. 2 shows a portion of the transistor device of FIG. 1 and a corresponding band structure.

FIG. 3 shows a cross-sectional side view of a portion of another embodiment of a transistor device with a contact to a junction region and a metal/semiconductor material interface having a conical shape.

FIG. 4 shows a cross-sectional side view of a portion of another embodiment of a transistor device with a dielectric material confining a contact to a junction region.

FIG. 5 shows another embodiment of a portion of a transistor device with a metal contact directly connected (directly in contact with) a channel of the device.

FIG. 6 is an interposer implementing one or more embodiments.

FIG. 7 illustrates an embodiment of a computing device.

### DETAILED DESCRIPTION

Techniques for reducing a contact resistance at a metal to semiconductor interface (a metal to semiconductor contact) are presented and as are transistor devices employing such techniques. In one embodiment, a contact resistance between a metal and a semiconductor material is reduced by grading a metal/semiconductor material interface to smooth out a band discontinuity. In one embodiment, the grading is achieved by confining (e.g., quantizing) a low density of states metal with the metal being more confined (e.g., more quantized) toward the semiconductor.

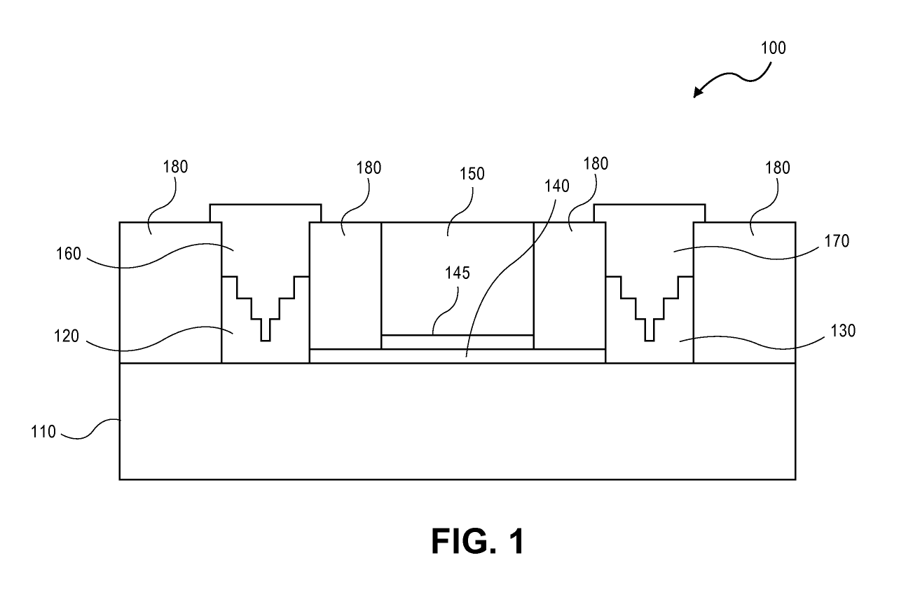

FIG. 1 shows a cross-sectional side view of an embodiment of a transistor device having metal contacts formed to junction regions of the device. Referring to FIG. 1, device structure 100 includes substrate 110 of a semiconductor material such as silicon, silicon germanium, germanium, a III-V, or a II-VI compound semiconductor. Disposed on substrate 110 is a transistor device including junction region 120 (e.g., a source), junction region 130 (e.g., a drain), channel 140 between the source and drain, gate dielectric 145 and gate electrode 150 on channel 140. Dielectric material 180 surrounds components of the device structure. In an embodiment where a transistor device is a field effect transistor (single or multi-gate transistor), junction region 120 and junction region 130 are a semiconductor material such as a doped silicon, silicon germanium, germanium, a III-V, or a II-VI compound semiconductor. In one embodiment, for a p-type device, junction region 120 and junction region 130 are each, for example, p⁺ silicon germanium or p⁺ silicon.

FIG. 1 shows metal contacts to each of junction region 120 and junction region 130. In one embodiment, a material of metal contact 160 and metal contact 170 to the respective junction regions is a low density of states metal. Examples of low density of states metals include but are not limited to antimony (Sb), bismuth (Bi), tin (Sn) and their alloys. These metals may be deposited by physical line of sight methods such as evaporation or sputtering or chemical means such as chemical vapor deposition (CVD) and atomical layer deposition (ALD). Chemical thin film deposition techniques include but are not limited to the use of a volatile metal chloride such as SbCl₃ or SnCl₄ as one precursor along with a coreactant such as hydrogen plasma or a homometal silyl coreactant such as Sb(SiR₃)₃ or Sn(SiR₃)₄ or Sn(SiR₃)₂, where R is an organic substituent including but not limited to methyl, ethyl, isopropyl, butyl or phenyl. In order to achieve a void free contact fill, the metal may or may not be annealed under an inert or reducing atmosphere such as one containing hydrogen. FIG. 1 shows the interface between the metal contact and semiconductor material of the junction (contact 160/junction region 120 and contact 170/junction region 130) as graded in the sense that the metal is increasingly confined by semiconductor material. FIG. 1 shows the metal to semiconductor material interface having a profile such that, proceeding in a direction toward substrate 110, the contact area between semiconductor material and metal taken through a horizontal cross-section of the interface (as viewed) gets progressively smaller. Such confinement tends to quantize a metal of the contact.

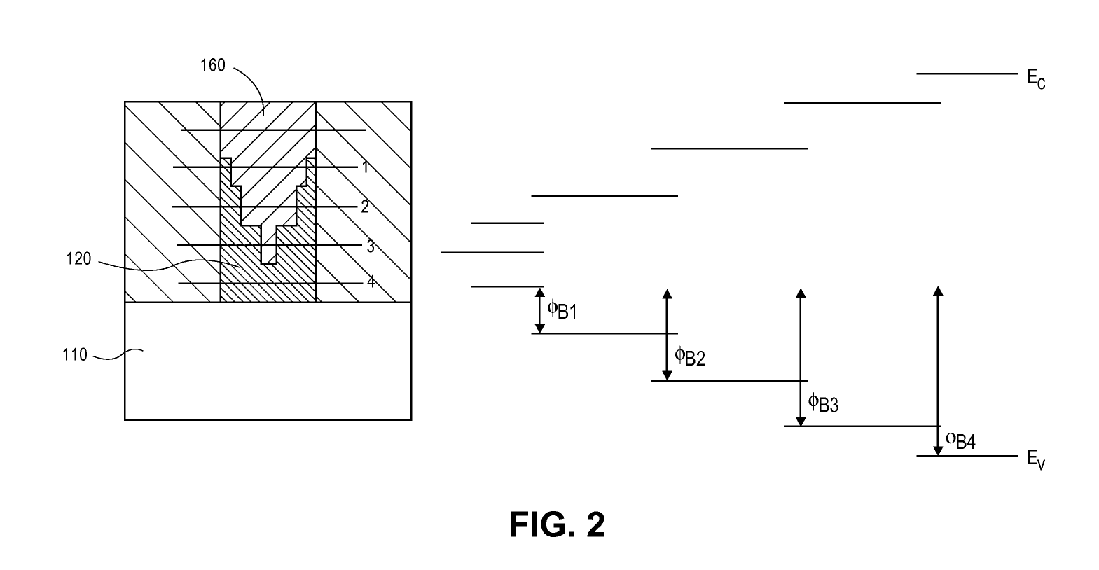

FIG. 2 shows a portion of the transistor device and a corresponding bandgap. FIG. 2 shows that the grading of the metal/semiconductor material interface to progressively confine (e.g., quantize) the metal results in a grading of the band discontinuity. FIG. 2 illustrates a barrier height at a first position (position 1) where a cross-sectional contact area between the metal and semiconductor material is dominated by metal material (least confined metal state) has a barrier height between a valence band and the metal work function. At a cross-section through the contact semiconductor material interface at a position 2, the metal material is becoming more confined by the semiconductor material resulting in a barrier height Φ_{B2}; at a position 3 even more confined resulting in the barrier height illustrated as Φ_{B3}; and finally at position 4 of only semiconductor material having a barrier height Φ_{B4}. Contact resistance is exponentially proportional to barrier height by the representation R=e^{Φ}^{_{B}}^{·k}. By breaking the barrier height into different sub-components (Φ_{B1}, Φ_{B2}, Φ_{B3} and Φ_{B4}), the resistance is reduced as e^{Φ}^{_{B1}}^{·k}+e^{Φ}^{_{B2}}^{·k}+e^{Φ}^{_{B3}}^{·k}+e^{Φ}^{_{B4}}^{·k} is less than e^{Φ}^{_{B}}^{·k}.

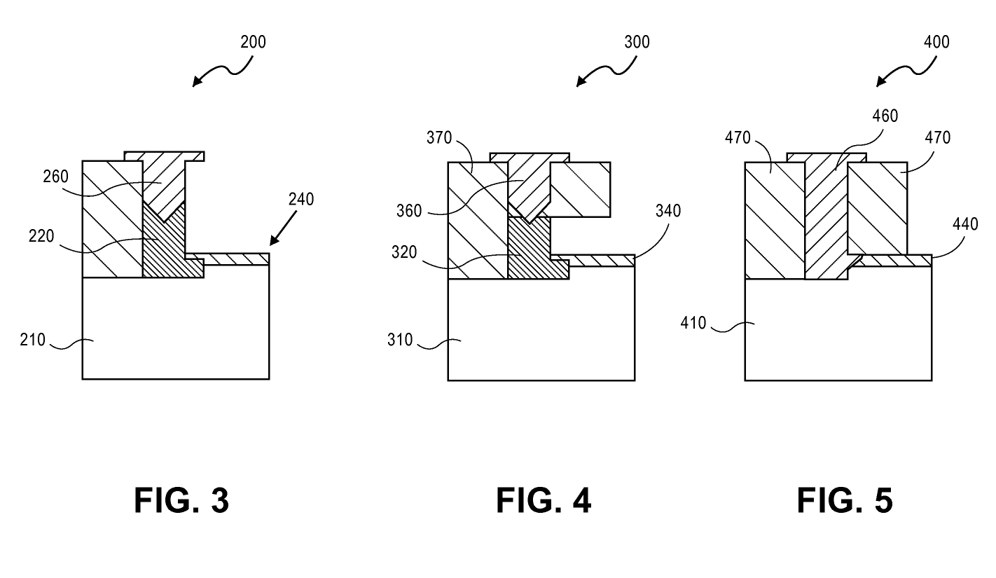

In the above embodiment, the interface between a metal and a semiconductor material is shown as graded or stepped. It is appreciated that other profiles of confinement will also be suitable. FIG. 3 shows a cross-sectional side view of a portion of another embodiment of a transistor device. Device 200 includes junction region 220 (e.g., a source or drain) at channel 240 on substrate 210 with metal contact 260 to junction region 220. FIG. 3 shows an interface having a conical shape. Either the graded interface (FIG. 1) or the conical interface of FIG. 3 may be formed by an etching process into the junction region material followed by metal deposition. In another embodiment, such a conical or stepped etch profile need not be precise (e.g., because of an etch recipe or tool property) but is suitable to the extent that the low density of states metal is confined (e.g., quantized) in a contact with a profile such as contact 260 or contact 160.

FIG. 4 shows a cross-sectional side view of a portion of another embodiment of a transistor device. FIG. 4 shows transistor device 300 including junction region 320 (e.g., a source or drain) and channel 340 on substrate 310. FIG. 4 also shows contact 360 to junction region 320. In this embodiment, contact 360 of, for example, a low density of states metal is confined by dielectric material 370. A dielectric material such as deposited silicon dioxide is a high bandgap material which as it confines the metal will reflect a band structure similar to that shown in FIG. 2 As illustrated, a cross-sectional area of metal contact 360 is reduced, in this embodiment, in a conical way in a direction toward junction region 320. In another embodiment, the confinement of metal contact 360 in a direction toward semiconductor material 320 can have other profiles including a step profile for a regular profile that similarly confines (e.g., quantizes) a metal material.

FIG. 5 shows another embodiment of a portion of a transistor device. Device 400 includes channel 440 formed on substrate 410 and metal contact 460 directly contacted to channel 440. In other words, a junction region (source or drain) of, for example, semiconductor material is removed and metal directly contacts channel 440 of the transistor device. As illustrated, contact 460 is defined through dielectric layer 470. As the metal contacts channel 440, the metal is confined by dielectric layer 470 at channel 440. Each of dielectric layer 470 and a low doped semiconductor material for channel 440 is a high bandgap material. The high bandgap will tend to increase the barrier. Thus, increasing a confinement of the metal, in this case, in a direction toward channel 440 will have a tendency to smooth out for junction and reduce a contact resistance.

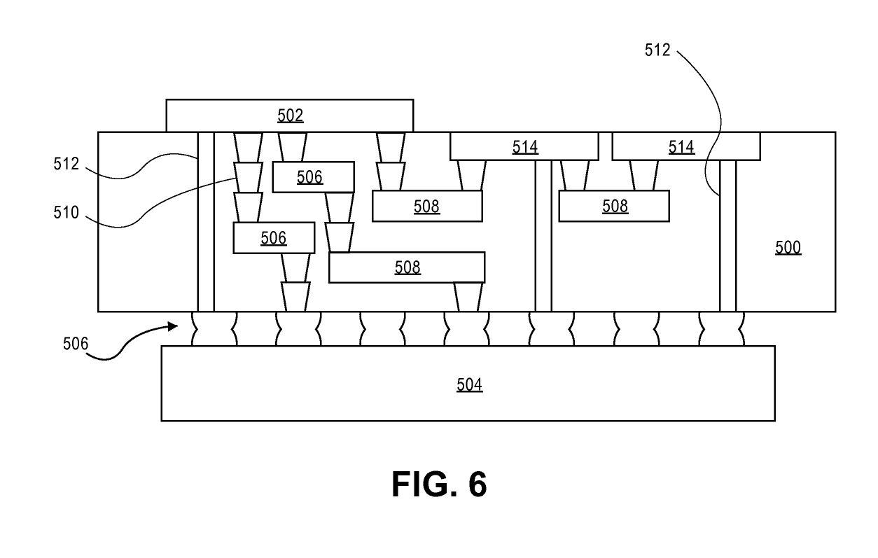

FIG. 6 illustrates interposer 500 that includes one or more embodiments. Interposer 500 is an intervening substrate used to bridge first substrate 502 to second substrate 504. First substrate 502 may be, for instance, an integrated circuit die. Second substrate 504 may be, for instance, a memory module, a computer motherboard, or another integrated circuit die. Generally, the purpose of interposer 500 is to spread a connection to a wider pitch or to reroute a connection to a different connection. For example, interposer 500 may couple an integrated circuit die to ball grid array (BGA) 506 that can subsequently be coupled to second substrate 504. In some embodiments, first and second substrates 502/504 are attached to opposing sides of interposer 500. In other embodiments, the first and second substrates 502/504 are attached to the same side of interposer 500. In further embodiments, three or more substrates are interconnected by way of interposer 500.

Interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on interposer 500.

In accordance with embodiments, apparatuses or processes disclosed herein may be used in the fabrication of interposer 500.

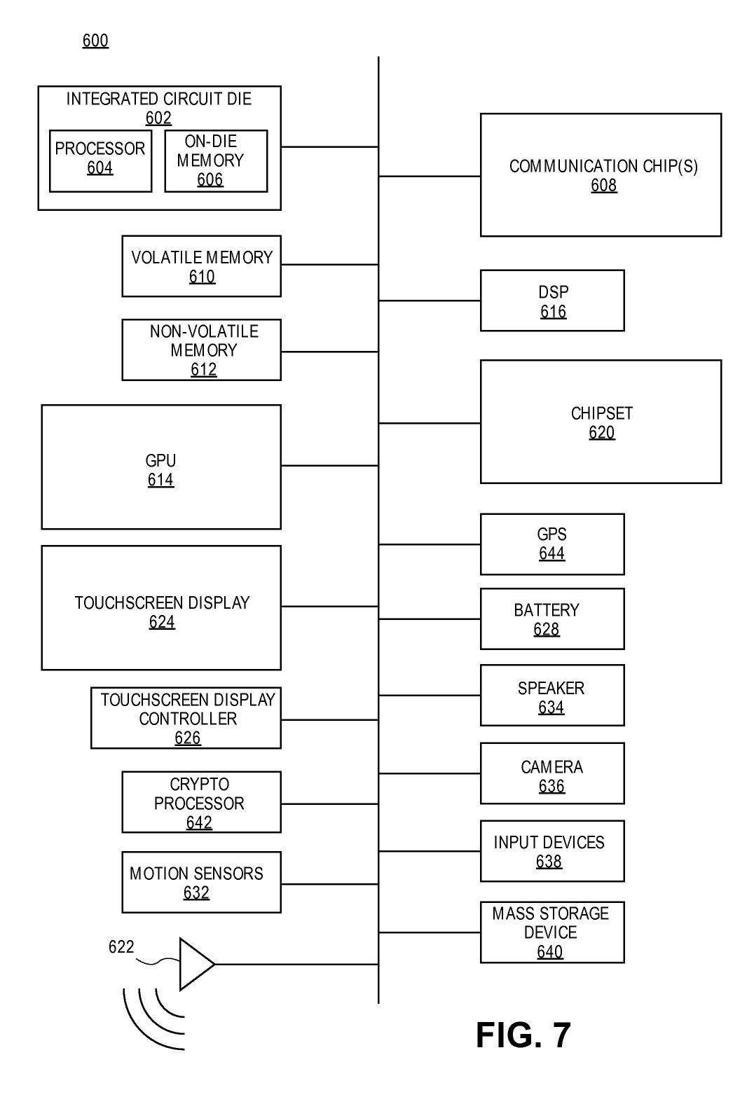

FIG. 7 illustrates a computing device in accordance with one embodiment. Computing device 600 may include a number of components. In one embodiment, these components are attached to one or more motherboards. In an alternate embodiment, these components are fabricated onto a single system-on-a-chip (SoC) die rather than a motherboard. The components in computing device 600 include, but are not limited to, integrated circuit die 602 and at least one communication chip 608. In some implementations the communication chip 608 is fabricated as part of integrated circuit die 602. Integrated circuit die 602 may include CPU 604 as well as on-die memory 606, often used as cache memory, that can be provided by technologies such as embedded DRAM (eDRAM) or spin-transfer torque memory (STTM or STTM-RAM).

Computing device 600 may include other components that may or may not be physically and electrically coupled to the motherboard or fabricated within an SoC die. These other components include, but are not limited to, volatile memory 610 (e.g., DRAM), non-volatile memory 612 (e.g., ROM or flash memory), a graphics processing unit 614 (GPU), digital signal processor 616, crypto processor 642 (a specialized processor that executes cryptographic algorithms within hardware), chipset 620, antenna 622, display or touchscreen display 624, touchscreen controller 626, battery 628 or other power source, power amplifier (not shown), global positioning system (GPS) device 644, compass 630, motion coprocessor or sensors 632 (that may include an accelerometer, a gyroscope, and a compass), speaker 634, camera 636, user input devices 638 (such as a keyboard, mouse, stylus, and touchpad), and mass storage device 640 (such as hard disk drive, compact disk (CD), digital versatile disk (DVD), and so forth).

Communications chip 608 enables wireless communications for the transfer of data to and from computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 600 may include a plurality of communication chips 608. For instance, first communication chip 608 may be dedicated to shorter range wireless communications such as Wi-Fi and Bluetooth and a second communication chip 608 may be dedicated to longer range wireless communications such as GPS, EDGE, GPRS, CDMA, WiMAX, LTE, Ev-DO, and others.

Processor 604 of computing device 600 includes one or more devices, such as transistors or metal interconnects, that are formed in accordance with embodiments including metal to semiconductor interfaces as described to confine a low density of states metal. The term “processor” may refer to any device or portion of a device that processes electronic data from registers and/or memory to transform that electronic data into other electronic data that may be stored in registers and/or memory.

Communication chip 608 may also include one or more devices, such as transistors or metal interconnects, that are formed in accordance with embodiments including metal to semiconductor interfaces as described to confine a low density of states metal.

In further embodiments, another component housed within computing device 600 may contain one or more devices, such as transistors or metal interconnects, that are formed in accordance with implementations including metal to semiconductor interfaces as described to confine a low density of states metal.

In various embodiments, computing device 600 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 600 may be any other electronic device that processes data.

### Examples

The following examples pertain to embodiments:

Example 1 is an apparatus including an integrated circuit device including at least one low density of state metal/semiconductor material interface, wherein the at least one low density of state metal is quantized.

In Example 2, the quantization of Example 1 is a graded quantization with the metal being more quantized at a first point of the interface than a second point of the interface.

In Example 3, a contact area of the metal and the semiconductor material at the interface of any of Example 1 or 2 is reduced in a graded manner.

In Example 4, the semiconductor material of any of Examples 1-3 includes a heavily doped semiconductor material.

In Example 5, a contact area of the metal and the semiconductor at the interface of Example 4 is reduced in a graded manner.

In Example 6, the metal of any of Examples 1-4 is confined in a dielectric material and the quantization is a graded quantization by the dielectric material, the metal being more quantized at the interface than at a point away from the interface.

In Example 7, the metal/semiconductor interface of any of Examples 1-4 includes a junction region of a transistor device.

In Example 8, the metal of Example 1 includes a contact and the semiconductor material a channel of a transistor device.

In Example 9, a contact area of the contact and the channel at the interface of Example 8 is reduced in a graded manner.

In Example 10, the at least one low density of states metal of any of Examples 1-4 includes antimony, bismuth, tin or their alloys.

Example 11 is an apparatus including a transistor including a gate dielectric layer formed on a substrate; a gate electrode formed on the gate dielectric layer; a source on one side of the gate electrode, a drain on an opposite side of the gate electrode and a channel between the source and drain, each of the source, drain and channel including semiconductor material; and a contact to one of the source and the drain, wherein the contact includes a low density of states metal and an interface of the a low density of states metal and a semiconductor material of one of the source and drain and the channel is graded.

In Example 12, the contact area of Example 11 is confined by the semiconductor material of the one of the source and drain or the channel and a contact area of the interface changes from a first area to a second area.

In Example 13, a first area of Example 12 is disposed a greater distance toward a metal side of the interface than the second area.

In Example 14, the semiconductor material of any of Examples 11-13 includes a heavily doped semiconductor material.

In Example 15, the semiconductor material of Example 14 includes the one of the source and the drain.

In Example 16, the apparatus of Example 11 includes a dielectric material on the transistor, wherein the contact is disposed through the dielectric material and the contact area of the metal is confined in the dielectric material.

In Example 17, the semiconductor material of Example 11 includes the channel.

In Example 18, the apparatus of Example 17 includes a dielectric material on the transistor, wherein the contact is disposed through the dielectric material and a contact area of the contact is confined by a dielectric material and the channel.

In Example 19, the at least one low density of states metal of any of Examples 11-18 includes antinomy, bismuth, tin or their alloys.

Example 20 is a method including confining a contact area of a semiconductor material; and forming a metal contact in the contact area.

In Example 21, confining a contact area of Example 20 includes grading a contact area of the semiconductor material from a first area to a smaller second area.

In Example 22, confining a contact area of any of Example 20 or 21 includes forming an opening in a dielectric material.

In Example 23, the semiconductor material of any of Example 20 or 21 includes a channel of a transistor device.

In Example 24, the metal of Example 20 includes a low density of states metal.

In Example 25, forming the metal of Example 24 includes depositing the metal by a chemical thin film technique and annealing under an inert or reducing atmosphere.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
an integrated circuit device comprising at least one low density of state metal/semiconductor material interface, wherein the at least one low density of state metal is quantized.

2. The apparatus of claim 1, wherein the quantization is a graded quantization with the metal being more quantized at a first point of the interface than a second point of the interface.

3. The apparatus of claim 2, wherein a contact area of the metal and the semiconductor material at the interface is reduced in a graded manner.

4. The apparatus of claim 1, wherein the semiconductor material comprises a heavily doped semiconductor material.

5. The apparatus of claim 4, wherein a contact area of the metal and the semiconductor at the interface is reduced in a graded manner.

6. The apparatus of claim 1, wherein the metal is confined in a dielectric material and the quantization is a graded quantization by the dielectric material, the metal being more quantized at the interface than at a point away from the interface.

7. The apparatus of claim 1, wherein the metal/semiconductor interface comprises a junction region of a transistor device.

8. The apparatus of claim 1, wherein the metal comprises a contact and the semiconductor material a channel of a transistor device.

9. The apparatus of claim 8, wherein a contact area of the contact and the channel at the interface is reduced in a graded manner.

10. The apparatus of claim 1, wherein the at least one low density of states metal comprises antimony, bismuth, tin or their alloys.

11. An apparatus comprising:
a transistor comprising:
a gate dielectric layer formed on a substrate;
a gate electrode formed on the gate dielectric layer;
a source on one side of the gate electrode, a drain on an opposite side of the gate electrode and a channel between the source and drain, each of the source, drain and channel comprising semiconductor material; and
a contact to one of the source and the drain, wherein the contact comprises a low density of states metal and an interface of a low density of states metal and a semiconductor material of one of the source and drain and the channel is graded.

12. The apparatus of claim 11, wherein the contact area is confined by the semiconductor material of one of the source and drain or the channel and a contact area of the interface changes from a first area to a second area.

13. The apparatus of claim 12, wherein a first area is disposed a greater distance toward a metal side of the interface than the second area.

14. The apparatus of claim 11, wherein the semiconductor material comprises a heavily doped semiconductor material.

15. The apparatus of claim 14, wherein the semiconductor material comprises the one of the source and the drain.

16. The apparatus of claim 11, further comprising a dielectric material on the transistor, wherein the contact is disposed through the dielectric material and the contact area of the metal is confined in the dielectric material.

17. The apparatus of claim 11, wherein the semiconductor material comprises the channel.

18. The apparatus of claim 17, further comprising a dielectric material on the transistor, wherein the contact is disposed through the dielectric material and a contact area of the contact is confined by a dielectric material and the channel.

19. The apparatus of claim 11, wherein the at least one low density of states metal comprises antinomy, bismuth, tin or their alloys.

20. A method comprising:
confining a contact area of a semiconductor material; and
forming a metal contact in the contact area.

21. The method of claim 20, wherein confining a contact area comprises grading a contact area of the semiconductor material from a first area to a smaller second area.

22. The method of claim 20, wherein confining a contact area comprises forming an opening in a dielectric material.

23. The method of claim 20, wherein the semiconductor material comprises a channel of a transistor device.

24. The method of claim 20, wherein the metal comprises a low density of states metal.

25. The method of claim 24, wherein forming the metal comprises depositing the metal by a chemical thin film technique and annealing under an inert or reducing atmosphere.
